(19) United States
(12) Patent Application Publication
(10) Pub. No.: US 2024/0363305 A1
(43) Pub. Date: Oct. 31, 2024

(54) STAGE DEVICE

(71) Applicant: Hitachi High-Tech Corporation, Tokyo (JP)

(72) Inventors: Motohiro TAKAHASHI, Tokyo (JP); Masaki MIZUOCHI, Tokyo (JP); Raifu YAMAMOTO, Tokyo (JP); Keiichiro HOSOBUCHI, Tokyo (JP); Takanori KATO, Tokyo (JP)

(73) Assignee: Hitachi High-Tech Corporation, Tokyo (JP)

(21) Appl. No.: 18/625,108

(22) Filed: Apr. 2, 2024

(30) Foreign Application Priority Data
Apr. 25, 2023 (JP) 2023-071454

(51) Int. Cl. H01J 37/20; H01J 37/28; H01L 21/687

(52) U.S. Cl. CPC H01J 37/20; H01L 21/68764; H01J 37/28; H01J 2237/20278

(57) ABSTRACT

A stage device includes a support stage supporting a target on which positioning is performed and a levitation mechanism levitating and positioning the support stage by a magnetic field. The stage device includes: a first motor configured to generate thrust in a first direction of the levitation mechanism; a second motor configured to generate thrust in a second direction different from the first direction; and a third motor configured to generate thrust in a third direction different from the first and second directions. In the first motor, the second motor, and the third motor, each of yokes on a non-levitation side corresponding to the each of motors shares the same member and is integrated. Each of the yokes that shares the same member and is integrated is disposed at both ends of a table in the second direction and a side of each yoke in the first direction is fixed to the table.

### CLAIM OF PRIORITY

The present application claims priority from Japanese Patent application serial no. 2023-071454, filed on Apr. 25, 2023, the content of which is hereby incorporated by reference into this application.

### BACKGROUND OF THE INVENTION

### 1. Field of the Invention

The present invention relates to a structure of a stage device and particularly to a technique applied and effective for a magnetic levitation type stage device.

### 2. Description of Related Art

In the related art, there are known techniques related to magnetic levitation stages accurately positioning and supporting wafers and device stages for semiconductor-related apparatuses.

For example, JP2015-198121A discloses a magnetic levitation stage mechanism moving a device. The magnetic levitation stage mechanism is a structure in which moving magnet type motors are used on XYZ axes and coils of stators are in a cantilever-like shape. In JP2015-198121A, motor thrust in three axis directions are generated by separate motors and contactless support is achieved.

JP2012-85386A discloses a stage device capable of inhibiting mutual interference of magnetic fields for axis driving of XY axes.

WO2022/264287A discloses a stage device capable of inhibiting leakage of a magnetic field and performing high-speed positioning.

For example, in processes of manufacturing, measuring, and inspecting semiconductor wafers, stage devices as in JP2015-198121A, JP2012-85386A, and WO2022/264287A are used to perform accurate positioning of semiconductor wafers. In such stage devices, high-speed and high-accurate positioning performance for semiconductor wafers is required.

However, in the magnetic levitation stage device of the related art as in JP2015-198121A, when a stroke in a longitudinal direction is large, stators are in a cantilever-like shape and vibrated. Therefore, there are problems that a natural frequency of the stage mechanism is low, there is restriction on an improvement in a control band, and it is difficult to achieve high-speed positioning. A yoke which is a magnetic substance of each axis of XYZ is required, and application to a charged particle beam apparatus is difficult due to a problem of a variation in a magnetic field or a leakage magnetic field.

In either JP2012-85386A or WO2022/264287A, the above problems are not adequately addressed and there is room for improvement.

### SUMMARY OF THE INVENTION

Accordingly, an object of the present invention is to provide a stage device capable of achieving high-speed positioning and a small leakage magnetic field while efficiently inhibiting vibration caused in driving in a magnetic levitation type stage device, a charged particle beam apparatus using the stage device, and a vacuum apparatus.

According to an aspect of the present invention, to solve the above problems, a stage device includes a support stage supporting a target on which positioning is performed and a levitation mechanism levitating and positioning the support stage by a magnetic field. The stage device includes: a first motor configured to generate thrust in a first direction of the levitation mechanism; a second motor configured to generate thrust in a second direction different from the first direction; and a third motor configured to generate thrust in a third direction different from the first and second directions. In the first motor, the second motor, and the third motor, each of yokes on a non-levitation side corresponding to the each of motors shares the same member and is integrated. Each of the yokes that shares the same member and is integrated is disposed at both ends of a table in the second direction and a side of each yoke in the first direction is fixed to the table.

According to the embodiment, it is possible to embody a stage device capable of achieving high-speed positioning and a small leakage magnetic field while efficiently inhibiting vibration caused in driving in a magnetic levitation type stage device, a charged particle beam apparatus using the stage device, and a vacuum apparatus.

Accordingly, it is possible to achieve performance improvement and reliability improvement of the charged particle beam apparatus or the vacuum apparatus on which the stage device is mounted.

Other problems, configurations, and advantages will be apparent in description of the following embodiments.

### BRIEF DESCRIPTION OF THE DRAWINGS

FIG. 1 is a diagram illustrating a stage device using a rolling guide of the related art;

FIG. 2 is a diagram illustrating a magnetic levitation type stage device of the related art;

FIG. 3 is a diagram illustrating a configuration example of an X axis motor of the magnetic levitation type stage device in FIG. 2;

FIG. 4 is a diagram illustrating a configuration example of a Y axis motor of the magnetic levitation type stage device in FIG. 2;

FIG. 5 is a diagram illustrating a configuration example of a Z axis motor of the magnetic levitation type stage device in FIG. 2;

FIG. 6 is a diagram illustrating another configuration example of the Z axis motor of the magnetic levitation type stage device in FIG. 2;

FIG. 7 is a sectional view illustrating the magnetic levitation type stage device in FIG. 2;

FIG. 8 is a diagram schematically illustrating a vibration mode in which a yoke of a Y axis motor is bent;

FIG. 9 is a diagram illustrating a magnetic levitation type stage device according to Example 1 of the present invention;

FIG. 10 is a sectional view illustrating the magnetic levitation type stage device in FIG. 9;

FIG. 11 is a sectional view illustrating a 3D composite motor of the magnetic levitation type stage device in FIG. 9;

FIG. 12 is a diagram illustrating a wiring example of an XY coil unit of the 3D composite motor of the magnetic levitation type stage device in FIG. 9;

FIG. 13 is a sectional view illustrating a 3D composite motor of a magnetic levitation type stage device according to Example 2 of the present invention; and

FIG. 14 is a diagram illustrating a semiconductor measurement apparatus according to Example 3 of the present invention.

### DESCRIPTION OF EMBODIMENTS

Hereinafter, examples of the present invention will be described with reference to the drawings. The same reference numerals denote the same configurations in each drawing, and detailed description of repeated portions will be omitted.

### Example 1

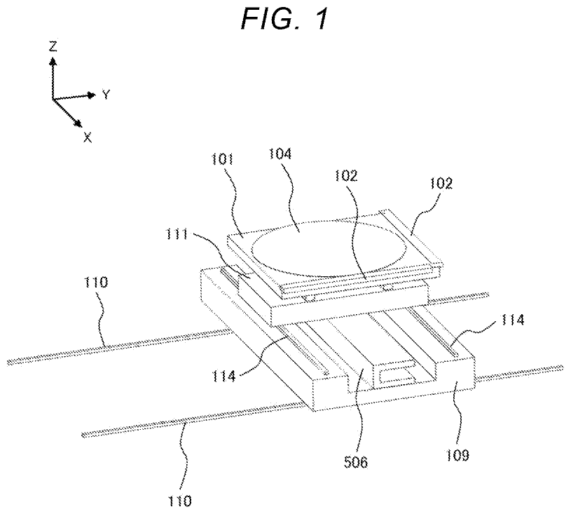

To easily understand the present invention, a structure and a problem of a stage device of the related art will first be described with reference to FIGS. 1 to 8.

FIG. 1 is a diagram illustrating a stage device using a rolling guide of the related art. A configuration example of a stack type stage using rolling guides on both the X and Y axes is illustrated.

A Y table 109 is guided by a Y axis guide 110 and an X table 111 is guided by an X axis guide 114. A top table 101 to which a sample 104 and a bar mirror 102 are fixed is mounted on the X able 111.

The bar mirror 102 is used to measure a position of the sample 104 for a laser interferometer or the like. A yoke 506 of a linear motor on the X axis is fixed to the Y table 109 and a coil (not illustrated) of the linear motor on the X axis is fixed to the X table 111. Accordingly, thrust in the X axis direction is given to the coil of linear motor of the X axis and the thrust in the X direction is given to the X table 111. In the yoke 506, reaction in an opposite direction to the thrust in the X axis direction occurs.

However, since the yoke 506 is fixed to the Y table 109 across in the entire X direction which is a longitudinal direction, a natural frequency of bending vibration of the yoke 506 is high and there is no problem in positioning.

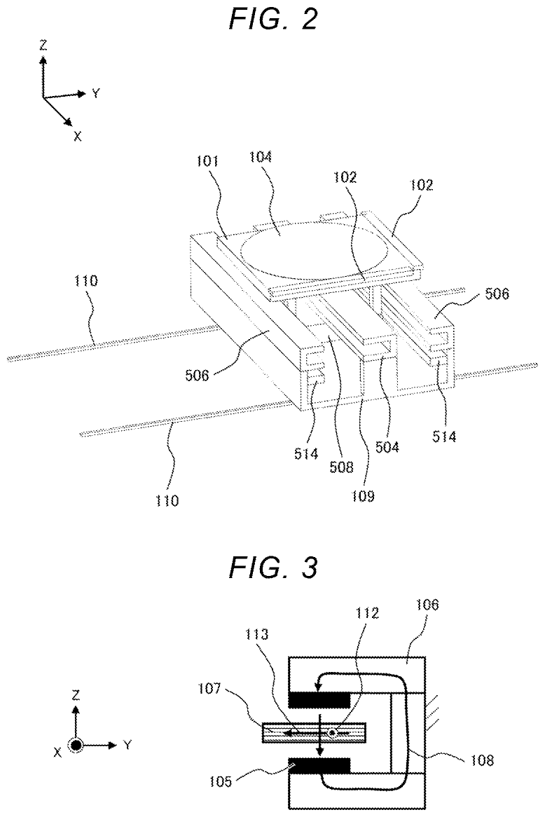

FIG. 2 is a diagram illustrating a magnetic levitation type stage device of the related art. A configuration in which the X axis guide 114 is magnetically levitated and guided with respect to the stage device using the rolling guide of FIG. 1.

In the magnetic levitation type stage device of the related art, it is necessary to perform control positions and orientations of six degrees of freedom including displacement of XYZ directions on the upper axis and rotation around the XYZ axes. Therefore, in the stage device of FIG. 1 in which the upper axis is not magnetically levitated, the number of motors on the X axis which is the upper axis may be one, but the number of axes of a motor corresponding a driving element increases to six axes. Specifically, the X axis guide 114 in FIG. 1 restricts displacement in the Y and Z directions, but this function is replaced with a Y axis motor and a Z axis motor in the magnetic levitation type stage device of the related art.

Since the yokes of the linear motors on the X, Y, and Z axes are located in a cantilever-like shape, the yokes easily vibrate.

In this way, in the magnetic levitation type stage device in which a stroke is long in one direction, many yokes of the linear motors are required for a cantilever-like structure, which results in a decrease in a natural frequency, limitation on a control band, and makes a high speed difficult. In addition, there is a problem of a deterioration in assembly or maintenance.

FIGS. 3 to 6 illustrate a configuration example of motors of XYZ axes of the magnetic levitation type stage device of the related art in FIG. 2.

FIG. 3 illustrates a configuration example of an X axis motor. A magnetic flux 108 is formed by a permanent magnet 105 and a U-shaped yoke 106. In a direction 113 of a current flowing in a coil 107, thrust 112 in the X direction is obtained by a Lorentz force.

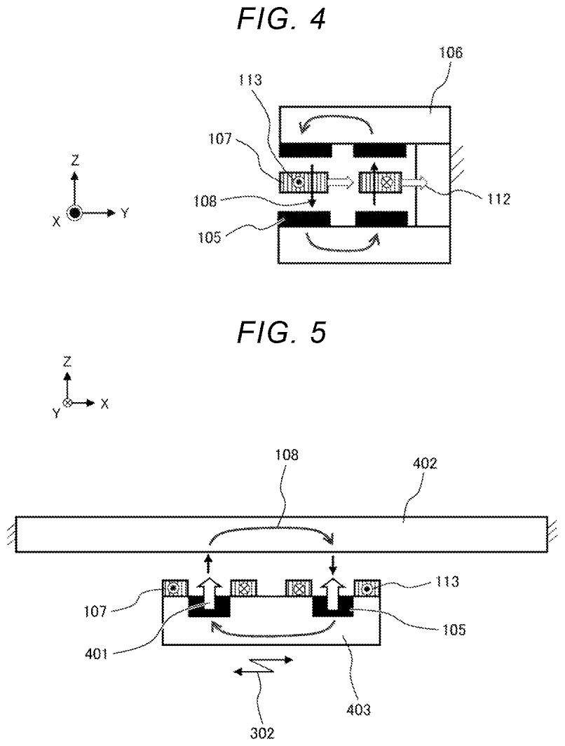

FIG. 4 illustrates a configuration example of a Y axis motor. The magnetic flux 108 is formed by the permanent magnet 105 and the U-shaped yoke 106. In the direction 113 of a current flowing in the coil 107, the thrust 112 in the Y direction is obtained by a Lorentz force.

FIG. 5 illustrates a configuration example of a Z axis motor. A magnetic attraction force 401 between a guide yoke 402 and two permanent magnets 105 is used for gravity compensation of a levitation unit. The magnetic flux 108 is formed in a loop form in the guide yoke 402 and a back yoke 403. By causing a current 113 to flow in the coil 107, the magnetic flux 108 is increased or decreased, and thus the magnetic attraction force 401 is increased and decreased. Accordingly, it is possible to control a force in the Z direction.

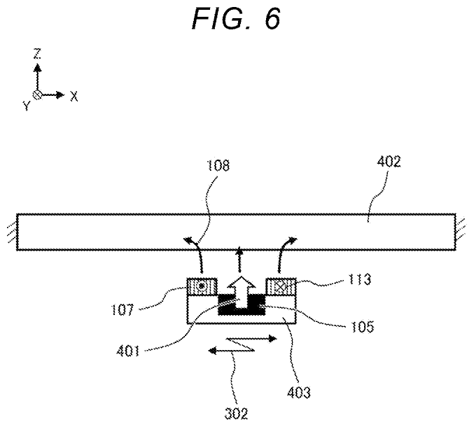

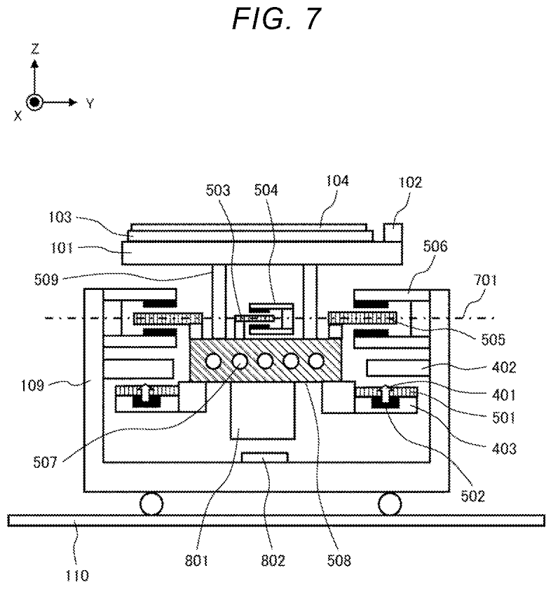

FIG. 6 is a diagram illustrating a configuration example of the Z axis motor different from that of FIG. 5. The number of permanent magnets 105 is one and the magnetic attraction force 401 is controlled with the current 113 in the coil 107.

FIG. 7 is a sectional view illustrating the magnetic levitation type stage device in FIG. 2. The motor in the configuration of FIG. 3 is mounted as an X axis motor and the yoke 506 corresponds to the yoke 106 in FIG. 3. The motor in the configuration of FIG. 4 is mounted as a Y axis motor and the yoke 504 corresponds to the yoke 106 in FIG. 4. The motor in the configuration of FIG. 5 or 6 is mounted as a Z axis motor.

A water-cooling pipe 507 is embedded in a water-cooling jacket 508. A position and an orientation of a scale plate 802 are measured by a scale head 801. A levitation unit is configured mainly from the water-cooling packet 508 and the top table 101.

When driving in the X and Y axes is performed, it is preferable to align heights of the X axis motor and the Y axis motor on a straight line 701 indicating a height of the center of gravity of the levitation unit and a driving center in order to inhibit occurrence of a pitching moment rotating around the center of gravity of the levitation unit. However, in this case, since the entire yoke longitudinal direction cannot be fixed to the Y table 109 from either the X axis motor or the Y axis motor, a cantilever-like structure of both supported ends is implemented as in a yoke 504 of the Y-axis motor in FIG. 2.

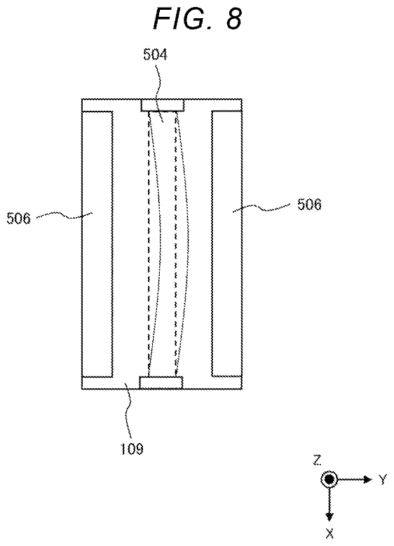

FIG. 8 schematically illustrates a vibration mode in which the yoke 504 of a Y axis motor is bent in the Y direction. Since the yoke 506 of the X axis motor can be fixed to the Y table 109 in the entire longitudinal direction, the yoke 506 does not vibrate. However, the yoke 504 of the Y axis motor has a cantilever-like structure of both supported ends and easily vibrates in an arch mode shape in the Y direction as in FIG. 8. In particular, since thrust in the Y direction is applied to the Y axis motor, the vibration mode is excited and a peak easily increases in a frequency response characteristic. Therefore, a control band in the Y direction is limited and it is difficult to implement a high speed.

As described above, the bending of the yoke 504 of the Y axis motor illustrated in FIG. 8 in the Y direction has been described. However, when the yoke 504 is moved at a high speed in the Z direction, bending of the Z guide yoke in the Z direction is similarly a problem.

As another problem of the configuration of the magnetic levitation type stage device of the related art in FIG. 7, there is deterioration in assembly and maintenance due to complication of the levitation unit and the yoke 504 of the Y axis motor.

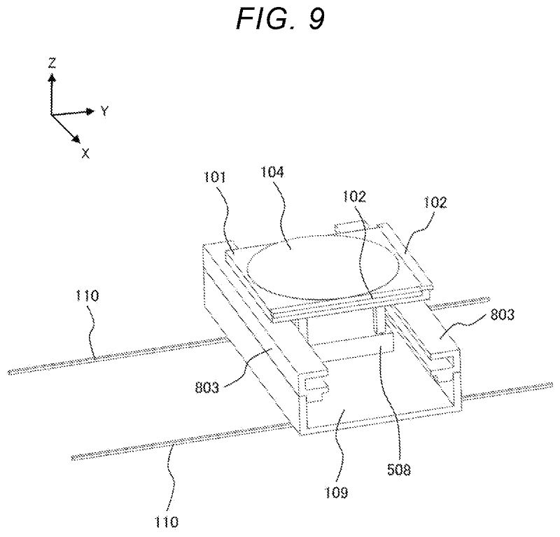

Next, a magnetic levitation type stage device according to Example 1 of the present invention will be described with reference to FIGS. 9 to 12.

FIG. 9 is a diagram illustrating a magnetic levitation type stage device on which a 3D composite motor is mounted according to the present invention to solve the above problems.

As illustrated in FIG. 9, in the present invention, since a motor of three XYZ axes has a motor structure in which a yoke is composite to one member (yoke) 803 and a yoke 803 can be fixed to the Y table 109 in the longitudinal direction (the Y direction), a natural frequency is high. That is, vibration of bending of the yoke 504 of the Y axis motor in the Y direction as in FIG. 8 or a natural frequency of vibration of bending of the yoke of the Z axis motor in the Z direction are considerably improved.

Therefore, a control band of which a rate is controlled by a natural frequency of the yoke in the magnetic levitation type stage device of the related art as in FIG. 2. The number of components provided in the magnetic levitation type stage device can be reduced and a lead time in an assembly process or maintenance can also be shortened.

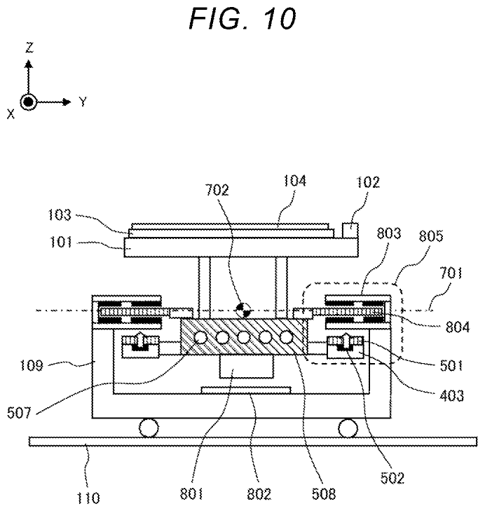

FIG. 10 is a sectional view illustrating the magnetic levitation type stage device in FIG. 9.

A height 701 of the gravity of center of the levitation unit can be matched with heights of a XY coil 804 of a 3D composite motor and the yoke 803 of a 3D composite motor obtaining thrust in the horizontal direction, a pitching moment in movement in the X and Y directions is small, a thrust of the Z axis motor for orientation control or change in an orientation is small, and thus low heating is possible.

By locating the yoke 803 of the 3D composite motor on the upper side of the permanent magnet 502 of the Z axis motor for gravity compensation of a levitation unit, a leakage magnetic field in the upper direction from the permanent magnet 502 of the Z axis motor is blocked.

The width of the yoke 803 of the 3D composite motor in the Y direction is broadened and a blocking effect is high with respect to the configuration of the magnetic levitation type stage device of the related art of FIG. 7. Therefore, it is possible to make application to an apparatus such as a charged particle beam apparatus in which a low magnetic field is required.

Since it is not necessary to locate a magnetic body such as the yoke 504 of the Y axis motor below the sample 104 as in FIG. 7, interference with a magnetic field in which a magnetic deflection lens of an electron optical system which is a problem in a charged particle beam apparatus or the like is reduced. Therefore, distortion of an electron beam is reduced, and thus a good image can be obtained.

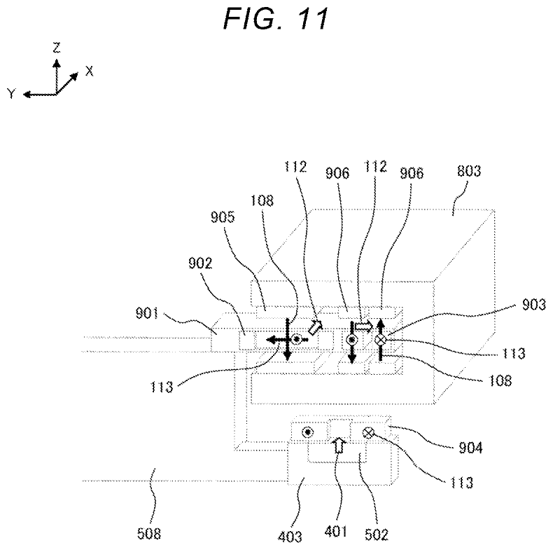

FIG. 11 is a sectional view illustrating a 3D composite motor. FIG. 11 is a sectional view illustrating an expanded range 805 of the 3D composite motor in FIG. 10.

As a principle that thrust of each axis of XYZ is generated is the same as that of each motor in FIGS. 3 to 6. For example, thrust 112 in the X axis direction is generated by the current 113 in an X axis thrust coil 902 and the magnetic flux 108 by an X axis thrust permanent magnet 905. Similarly, the thrust 112 in the Y axis direction is generated by the current 113 in a Y axis thrust coil 903 and the magnetic flus 108 by a Y axis thrust permanent magnet 906. A magnetic attraction force 401 in the Z direction is used for gravity compensation of the levitation unit, and the magnetic attraction force 401 is increased or decreased by the current 113 in a Z axis thrust coil 904 for thrust control in the Z direction, and thus the X axis thrust coil 902 obtaining the thrust 112 in the X direction for thrust control in the Z direction and the Y axis thrust coil 903 obtaining the thrust 112 in the Y direction are placed in a coil mold 901.

In this way, the magnetic levitation type stage device according to the present example is configured such that thrust of three axes can be independently generated while sharing (integrating) the yoke member 803 for each motor of the XYZ axes.

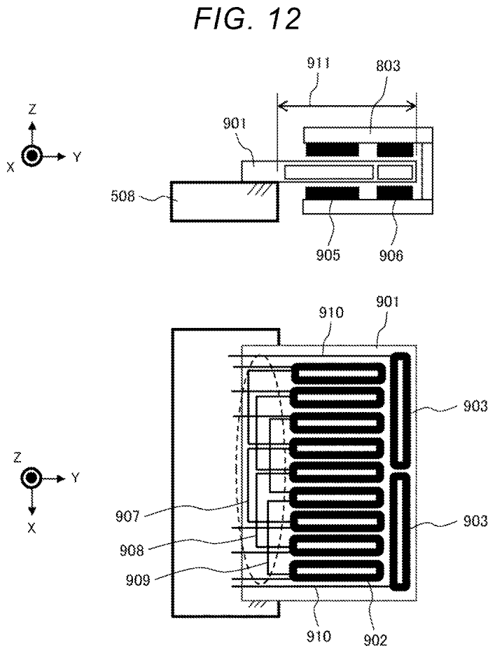

An example of an inner wiring structure of a coil (XY coil) obtaining horizontal thrust of the 3D composite motor will be described with reference to FIG. 12.

When the X axis thrust coil 902 and the Y axis thrust coil 903 are disposed, the Y axis thrust coil 903 is preferably disposed on the back side (the right side of the X axis thrust coil 902 in FIG. 12) of the yoke 803 of the 3D composite motor. Since the X axis motor is of a three-phase alternating current motor, a wiring 907 connecting U phases, a wiring 908 connecting V phases, and a wiring 909 connecting W phases are required for a coil of UVW, the UVW being three phases. It is necessary to place these wirings in the coil mold 901.

When the coil mold 901 vibrates in the Z direction, the levitation unit vibrates and the sample 104 or the bar mirror 102 vibrates, which is not preferable. Therefore, a coil extrusion length 911 of the coil mold 901 is preferably reduced as small as possible.

Accordingly, by locating the Y axis thrust coil 903 at a distal end (the back side of the yoke 803 of the 3D composite motor) and locating the X axis thrust coil 902 in which a wiring space of three phases is necessary on a base side, it is possible to minimize the coil extrusion length 911. That is, from a relation between the coil wirings and the coil extrusion length 911, there is a necessity to locate the Y-axis thrust coil 903 on the back side of the coil mold 901.

The stage device according to the present example has the foregoing configuration and includes a support stage (top table 101) supporting a target (sample 104) on which positioning is performed and a levitation mechanism levitating and positioning the support stage (the top table 101) by a magnetic field, a first motor (X axis motor) configured to generate thrust in a first direction of the levitation mechanism, a second motor (Y axis motor) configured to generate thrust in a second direction different from the first direction, and a third motor (Z axis motor) configured to generate thrust in a third direction different from the first and second directions. In the first motor (X axis motor), the second motor (Y axis motor), and the third motor (Z axis motor), each of yokes (the X yoke, the Y yoke, and the Z yoke) on a non-levitation side corresponding to each of the motors shares the same member 803 and is integrated. Each of the yokes (the X yoke, the Y yoke, and the Z yoke) that shares the same member 803 and is integrated is disposed at both ends of a table (Y table 109) in the second direction (Y direction 109) and a side of each yoke in the first direction (X direction) is fixed to the table.

For example, the second direction is a direction perpendicular to the first direction. The third direction is a direction perpendicular to the first and second directions. That is, the X and Y axes are perpendicular to each other on a horizontal plane and the Z axis is vertical to the horizontal plane.

The X yoke, the Y yoke, and the Z yoke that share the same member 803 and are integrated and has a cross-section with a U shape.

Lower surfaces of the X yoke, the Y yoke, and the Z yoke that share the same member 803 and are integrated are used for magnetic attraction of the Z axis motor.

Each of the coils of the X axis motor, the Y axis motor, and the Z axis motor is collectively coil-molded (901).

The coil of the Y axis motor and the coil of the X axis motor are flush with each other and are disposed on a back side of the U-shaped yokes.

Accordingly, in the magnetic levitation type stage device, it is possible to embody the stage device capable of achieving high-speed positioning and a small leakage magnetic field while efficiently inhibiting vibration caused in driving.

### Example 2

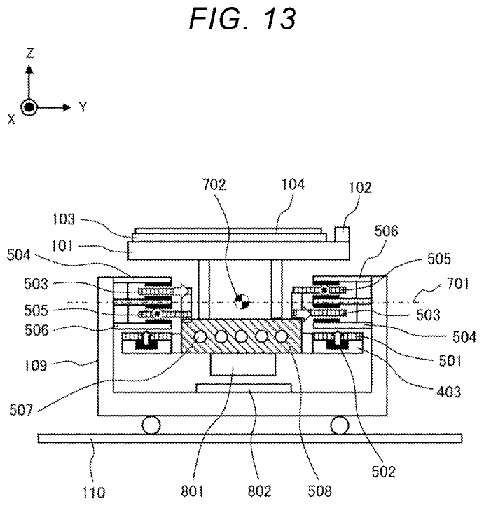

A magnetic levitation type stage device according to Example 2 of the present invention will be described with reference to FIG. 13.

FIG. 13 is a sectional view illustrating a 3D composite motor of a magnetic levitation type stage device according to the present example. In Example 1 (FIG. 10), the thrust generation units of the X and Y axes are located horizontally. In the present example (FIG. 13), the thrust generation units of the X and Y axes are located vertically unlike Example 1 (FIG. 10). Other configurations are similar to those of Example 1 (FIG. 10).

The thrust generation unit of the X axis includes the yoke 506 of the X axis motor and a coil 505 of the X axis motor, and the thrust generation unit of the Y axis includes the yoke 504 of the Y axis motor and a coil 503 of the Y axis motor.

In FIG. 13, on the right side, the thrust generation unit (505, 506) of the X axis is disposed above the thrust generation unit (503, 504) of the Y axis. On the left side, the thrust generation unit (503, 504) of the Y axis is disposed above the thrust generation unit (505, 506) of the X axis.

Accordingly, in the entire magnetic levitation type stage device, an operational point of thrust during movement in the X direction and during movement in the Y direction can be adjusted to a height 701 of the center of gravity 702 and a pitching moment can be inhibited from being generated.

Both the yoke 506 of the X axis motor and the yoke 504 of the Y axis motor can be fixed to the Y table 109 in the entire longitudinal direction, which contributes to low vibration.

The stage device according to the present example has the foregoing configuration, and thus the X axis motor and the Y axis motor overlap in the vertical direction and a vertical relation between the X axis motor and the Y axis motor is reversed symmetrically on an XZ plane.

The X axis motor and the Y axis motor are disposed so that heights of the X axis motor and the Y axis motor are staggered at height.

In the present example, as in Example 1, it is possible to embody the stage device capable of achieving high-speed positioning and a small leakage magnetic field while efficiently inhibiting vibration caused in driving.

### Example 3

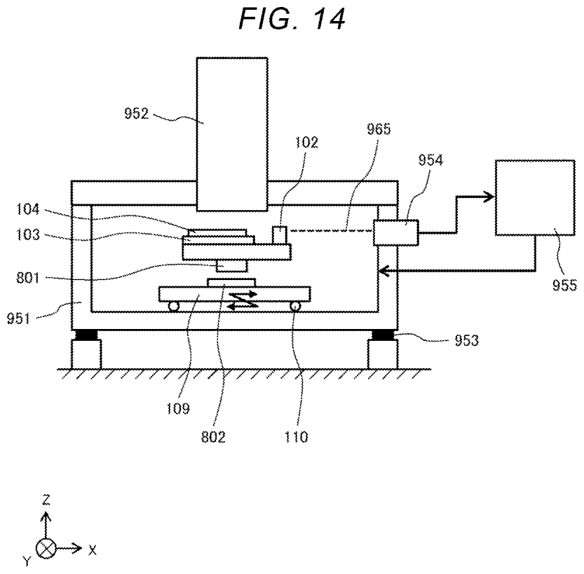

A charged particle beam apparatus and a vacuum apparatus according to Example 3 of the present invention will be described with reference to FIG. 14.

FIG. 14 is a diagram illustrating a semiconductor measurement apparatus such as a charged particle beam apparatus or a vacuum apparatus on which a magnetic levitation type stage device that has a 3D composite motor structure according to the present invention is mounted.

As illustrated in FIG. 14, the semiconductor measurement apparatus includes a stage device that positions a target (the sample 104) and a vacuum chamber 951 that houses the stage device. The semiconductor measurement apparatus according to the present example is, for example, a measurement scanning electron microscope (SEM) which is an application apparatus of an SEM.

The semiconductor measurement apparatus includes, for example, the stage device, the vacuum chamber 951, an electron optical system lens-barrel 952, a vibration control mount 953, a laser interferometer 954, a scale head 801, a scale plate 802, and a controller 955.

The vacuum chamber 951 houses the stage device and is in a vacuum state in which a pressure is lower than the atmospheric pressure by reducing the pressure inside by a vacuum pump (not illustrated). The vacuum chamber 951 is supported by the vibration control mount 953.

In the semiconductor measurement apparatus, the stage device positions a target (the sample 104) such as a semiconductor wafer, an electron beam is radiated to the target (the sample 104) from the electron optical system lens-barrel 952, a pattern of an image of the target (the sample 104) is imaged, and measurement of a line width of the pattern or evaluation of shape accuracy are performed.

In the stage device, the laser interferometer 954 measures a position of the bar mirror 102, the scale head 801 measures a position of the scale plate 802, the controller 955 controls positioning of the target (the sample 104) such as semiconductor wafer held on a sample sand 103 on the support stage.

The semiconductor measurement apparatus according to the present example includes the stage device in which vibration of the 3D composite motor structure is low, and thus a reduction in vibration during positioning of a target such as a semiconductor wafer and a reduction in time of positioning can be achieved, and leakage of a magnetic field can be inhibited.

Accordingly, for example, it is possible to improve measurement accuracy of the charged particle beam apparatus. Since the levitation mechanism is a magnetic levitation type mechanism, the stage device is easily applied to the semiconductor measurement apparatus which is a vacuum apparatus, and exhibit excellent advantages such as a reduction in contamination or suppression of heat.

The charged particle beam apparatus and the vacuum apparatus according to the present example are not limited to a measurement apparatus for semiconductor and can also be applied to a measurement apparatus used in other fields.

The present invention is not limited to the foregoing examples, but includes various modified examples. For example, the foregoing examples have been described in detail for clear description of the present invention and all the described components may not be included. Some of the components in a certain example can be replaced with components in another example, the components in another example can also be added to the components in the certain example. Other components can be added to, deleted from, or replaced with some of the components in each example.

What is claimed is:

1. A stage device that includes a support stage supporting a target on which positioning is performed and a levitation mechanism levitating and positioning the support stage by a magnetic field, the stage device comprising:
a first motor configured to generate thrust in a first direction of the levitation mechanism;
a second motor configured to generate thrust in a second direction different from the first direction; and
a third motor configured to generate thrust in a third direction different from the first and second directions,
wherein in the first motor, the second motor, and the third motor, each of yokes on a non-levitation side corresponding to the each of motors shares the same member and is integrated, and
wherein each of the yokes that shares the same member and is integrated is disposed at both ends of a table in the second direction and a side of each yoke in the first direction is fixed to the table.

2. The stage device according to claim 1,
wherein the second direction is a direction perpendicular to the first direction, and
wherein the third direction is a direction perpendicular to the first and second directions.

3. The stage device according to claim 1,
wherein the first motor, the second motor, and third motor are an X axis motor, a Y axis motor, and Z axis motor, respectively,
wherein, in the X axis motor, the Y axis motor, and the Z axis motor of the levitation mechanism, an X yoke, a Y yoke, and a Z yoke on the non-levitation side corresponding to the each of motors shares the same member and is integrated, and
wherein the X yoke, the Y yoke, and the Z yoke that share the same member and are integrated are disposed at both ends of a Y table in a Y direction and side of each yoke in an X direction is fixed to the Y table.

4. The stage device according to claim 3,
wherein the X and Y axes are perpendicular to each other on a horizontal plane, and
wherein the Z axis is vertical to the horizontal plane.

5. The stage device according to claim 3, wherein the X yoke, the Y yoke, and the Z yoke that share the same member and are integrated has a cross-section with a U shape.

6. The stage device according to claim 5, wherein lower surfaces of the X yoke, the Y yoke, and the Z yoke that share the same member and are integrated are used for magnetic attraction of the Z axis motor.

7. The stage device according to claim 6, wherein coils of the X axis motor, the Y axis motor, and the Z axis motor are collectively coil-molded.

8. The stage device according to claim 7, wherein the coil of the Y axis motor and the coil of the X axis motor are flush with each other and are disposed on a back side of the U-shaped yokes.

9. The stage device according to claim 6, wherein the X axis motor and the Y axis motor are overlapped and disposed in a vertical direction and a vertical relation between the X axis motor and the Y axis motor is reversed symmetrically on an XZ plane.

10. The stage device according to claim 3, wherein the X axis motor and the Y axis motor are disposed so that heights of the X axis motor and the Y axis motor are staggered at height.

11. The stage device according to claim 1, wherein the stage device is mounted on a charged particle beam apparatus or a vacuum apparatus.
